(19) United States
(12) Patent Application Publication
(10) Pub. No.: US 2010/0258845 A1
(43) Pub. Date: Oct. 14, 2010

(54) Semiconductor device and method for manufacturing same

(75) Inventors: Toshiharu Marui, Tokyo (JP); Fumihiko Toda, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 12/659,336

(22) Filed: Mar. 4, 2010

(30) Foreign Application Priority Data
Apr. 13, 2009 (JP) 2009-097085

(51) Int. Cl. H01L 29/778; H01L 21/20

(52) U.S. Cl. 257/194; 438/478; 257/E29.246; 257/E21.09

(57) ABSTRACT

There is provided a semiconductor device capable of deactivating 2-dimensional electron gas (2DEG) layers in a buffer layer having a multi-layer film structure. The buffer layer is formed in a high electron mobility transistor (HEMT) formed on a silicon (Si) substrate. The semiconductor device includes the substrate whose uppermost layer is the Si layer, the buffer layer constructed by alternately stacking a plurality of first layers and a plurality of second layers on the Si layer, third layer serving as an electron transit layer formed on the buffer layer, and fourth layer serving as an electron supplying layer formed on the third layer. The first layer is composed of the same material as for the third layer. A p-type impurity is introduced into the first layers so as to deactivate the 2DEG layers formed in the first layer near interfaces between the first and second layers.

### BACKGROUND OF THE INVENTION

1. Field of the Invention

The present invention relates to a semiconductor device and a method of manufacturing the same, and in particularly to a structure of a buffer layer in high electron mobility transistor (HEMT) using a silicon (Si) substrate.

2. Description of the Related Art

A high electron mobility transistor (HEMT) is conventionally known as a field effect transistor utilizing a 2-dimensional electron gas (2DEG) layer as a current path. The HEMT is constructed on a substrate by sequentially forming an electron transit layer composed of, for example, GaN into which no impurity is introduced and an electron supplying layer composed of, for example, AlGaN. The 2DEG layer is formed in the electron transit layer at a heterojunction interface between the electron transit layer and the electron supplying layer due to either piezopolarization or spontaneous polarization, or due to both. The HEMT using the 2DEG layer is highly expected to provide an excellent electronic device since it can be excellent in high-temperature operations, high-speed switching operations, large-power operations and the like.

However, when the HEMT is formed on a silicon substrate (hereinafter, also called Si substrate), tensile stress occurs in the electron transit layer and the electron supplying layer when the device is driven. The tensile stress is ascribed to a difference in thermal expansion coefficients between the Si substrate and a layered structure including the electron transit layer and the electron supplying layer respectively composed of, for example, GaN and AlGaN. Therefore, there is a big fear of the occurrence of a problem that a crack and/or warpage of the substrate or the like may occur due to the tensile stress in the HEMT using the Si substrate.

A technology for the reduction of the tensile stress is known in which a buffer layer having a multi-layered structure is formed between the Si substrate and the electron transit layer. A semiconductor device relating with the present invention is disclosed in IEICE Technical Report ED2007-168, CPM2007-94, LQE2007-69, 2007-10 (Document 1) and will now be described.

FIG. 1 shows a schematic diagram of a related semiconductor device disclosed in the Document 1 and also a cross-sectional view taken along a thickness direction of a substrate of the semiconductor device.

In the semiconductor device disclosed in the Document 1, a GaN layer and an AlGaN layer respectively serving as an electron transit layer 105 and an electron supplying layer 107 are alternately stacked via a buffer layer 103 on the substrate, and thus an AlGaN/GaN-HEMT is formed. Moreover, in the semiconductor device disclosed in the Document 1, a thin AlN layer 109 is formed between the electron transit layer 105 and the electron supplying layer 107 for the sake of improving electron mobility of a 2DEG layer 111 formed in the electron transit layer 105.

Also, the buffer layer 103 has a multi-layered film structure to reduce the tensile stress described above. More specifically, in consideration of lattice constant matching between the GaN layer of the electron transit layer 105 and the AlGaN layer of the electron supplying layer 107, the buffer layer 103 is composed of materials of AlN and GaN having lattice constants similar to or the same as those of GaN and AlGaN. That is, the buffer layer 103 is constructed to have a multi-layered film structure in which a plurality of AlN layers 113 and a plurality of GaN layers 115 are alternately stacked.

In the semiconductor device described in the Document 1, the buffer layer 103 having such a multi-layered film structure is formed, so that the tensile stress described above can be reduced and thus, for example, cracks and/or warpage of the substrate can be prevented even when the device is driven

However, in the semiconductor device described in the Document 1, residual carriers are produced in the GaN layers 115 of the layer-stacked structure formed by the AlN layers 113 and the GaN layers 115 of the buffer layer 103, thus causing the 2DEG layers in the GaN layers 115. As a result, the semiconductor device described in the Document 1 has a problem in that high-frequency property is degraded due to decreased resistance of a layer-stacked structure including the Si substrate and buffer layer 103.

FIG. 2 is a diagram showing a carrier density distribution as a function of thickness, which is obtained by performing capacitance-voltage (CV) measurement to measure a carrier profile for the semiconductor device described in the Document 1.

The carrier profile is obtained for a sample shown in FIG. 2 having the following structural body. An AlN layer 113 having a thickness of 4 nm and a GaN layer 115 having a thickness of 16 nm were alternately stacked, so that the buffer layer 103 having a thickness of 400 nm was obtained including twenty AlN layers 113 and twenty GaN layers 115. On the buffer layer 103, an electron transit layer 105 with a thickness of 1000 nm, an AlN thin layer 109 with a thickness of 1 nm, and an electron supplying layer 107 with a thickness of 25 nm were sequentially formed. In addition, a GaN cap layer with a thickness of 5 nm was formed on the electron supplying layer 107 in the sample.

The vertical and horizontal axes of FIG. 2 respectively show a carrier density in a unit of cm⁻³ and a depth from a surface of the GaN cap layer of the sample in a unit of nm.

It is understood from the distribution of FIG. 2 that the carriers are generated at depths of 90 nm, 300 nm, and 1400 nm in the semiconductor device in the Document 1. Carriers 117 and 119 distributed at the depths of 90 nm and 300 nm are generated in the 2DEG layer 111 formed in the electron transit layer 105. Carriers 121 distributed at the depth of 1400 nm having a density of 2.4×10¹⁵ cm⁻³ are generated in the 2DEG layer 111 formed in the GaN layer 115 of the buffer layer 103.

As described above, high-frequency property is degraded ascribing to the generation of the carriers in the buffer layer 103. Advantageous technologies for suppressing the generation of carriers in the buffer layer 103 have been desired. The carrier density in the buffer layer 103 is preferably less than 1×10¹⁵ cm⁻³ at which degradation of high-frequency property can be suppressed.

### SUMMARY OF THE INVENTION

It is an object of the present invention to provide a semiconductor device capable of suppressing generation of carriers in a buffer layer and deactivating a 2DEG layer generated in the buffer layer.

To achieve the object, the semiconductor device of the present invention has the following features.

According to a first aspect of the present invention, there is provided a semiconductor device including a substrate whose uppermost layer is a Si layer; a buffer layer formed by alternately stacking a plurality of first layers and a plurality of second layers on the Si layer; a third layer for serving as an electron transit layer formed on the buffer layer; and a fourth layer for serving as an electron supplying layer formed on the third layer. The first layers are composed of a material identical to a material the third layers and a p-type impurity is introduced into the first layers so as to deactivate 2-dimensional electron gas layers formed in said first layers near interfaces between the first and second layers.

According to a second aspect of the present invention, there is provided a method for manufacturing a semiconductor device including a first step of alternately stacking a plurality of first layers and a plurality of second layers on a substrate whose uppermost layer is an Si layer so as to form a buffer layer on the Si layer; and a second step of forming sequentially a third layer serving as an electron transit layer and a fourth layer serving as an electron supplying layer on the buffer layer; wherein, in the first step, the first layers are formed a material identical to a material of the third layers and wherein a p-type impurity is introduced into the first layers so as to deactivate 2-dimensional electron gas layers formed at interfaces between the first layers and the second layers.

In the first aspect of the semiconductor device of the present invention, the buffer layer is constructed by alternately stacking a plurality of first layers and a plurality of second layers. A p-type impurity is introduced into the first layers. Therefore, it is possible to reduce the density of carriers generated in the first layers at an interface between the first and second layers. As a result, in the semiconductor device of the present invention, the 2DEG layers generated in the first layers at the interface between the first and second layers can be suppressed, and thus the 2DEG layers can be deactivated.

In the second aspect of the method of manufacturing the semiconductor device of the present invention, the p-type impurity is introduced into the first layers of the buffer layer in the first step. Therefore, in the manufacturing method of the semiconductor device of the present invention, it is possible to manufacture the semiconductor device whose 2DEG layers generated in the first layers at the interfaces between the first and second layers are deactivated.

### BRIEF DESCRIPTION OF THE DRAWINGS

FIG. 1 shows a schematic diagram of a semiconductor device according to a related art of the Document 1 and a cross-sectional view taken along a thickness direction of the semiconductor device.

FIG. 2 is a diagram showing carrier density distribution as a function of a thickness obtained by performing carrier profiling by CV measurement on the semiconductor device described in the Document 1.

FIG. 3 is a schematic view illustrating an embodiment of the present invention and is a cross-sectional view taken along a direction of a thickness of the semiconductor device along its gate-length direction.

FIGS. 4A and 4B are diagrams illustrating an experiment to confirm effects of introduction of a p-type impurity, and each of FIGS. 4A and 4B is a cross-sectional view of a structural body used as a sample for the experiment taken along a thickness direction.

FIGS. 5A and 5B are process diagrams illustrating the method for manufacturing the semiconductor device 10 of the embodiment of the present invention.

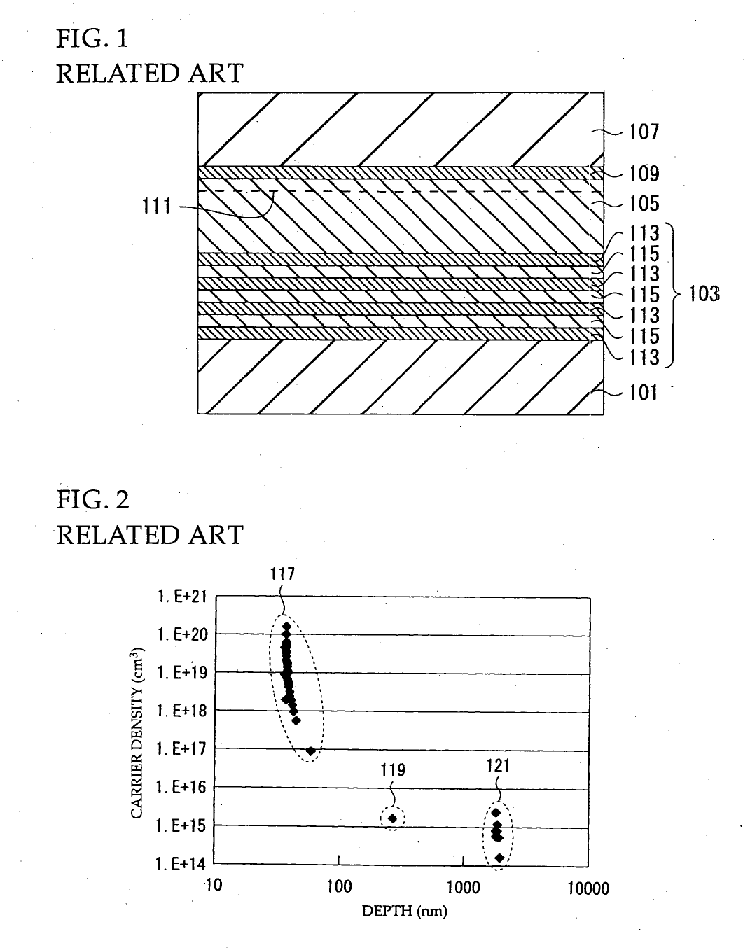

### DETAILED DESCRIPTION OF THE INVENTION

Semiconductor devices of embodiments of the present invention will now be described with reference to attached drawings. Each of the drawings simply shows a shape, size, and arrangement of each component by which the present invention can be understood. Therefore, the present invention is not limited to configurations shown in the drawings.

### First Embodiment

In a first embodiment of the present invention, a semiconductor device and a method of manufacturing the same will now be described. The semiconductor device utilizes a substrate whose uppermost layer is a Si layer and is constructed to include a buffer layer of a multi-layered structure having a plurality of first layers and a plurality of second layers. A p-type impurity is introduced into the first layers of the multi-layered structure, thus deactivating 2DEG layers formed in first layers of the buffer layer.

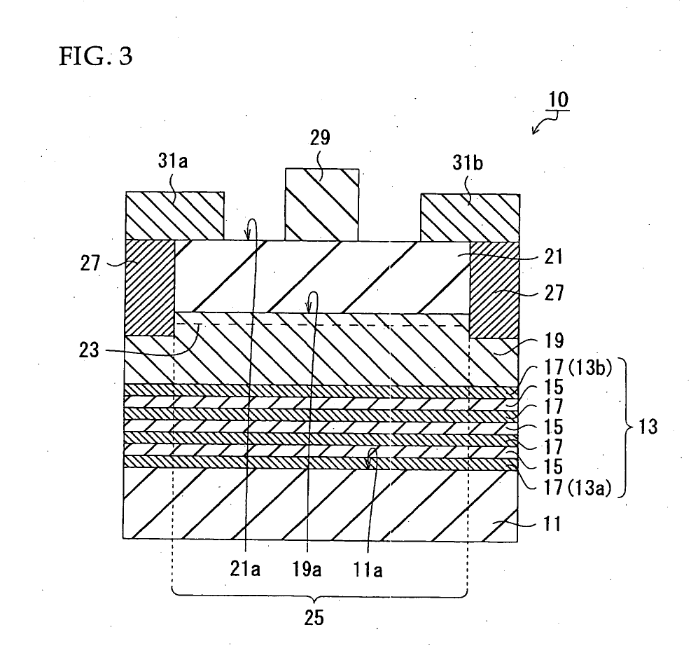

FIG. 3 shows a schematic view of the first embodiment of the present invention and a cross-sectional view in a direction of a thickness of the semiconductor device along its gate-length direction.

A semiconductor device 10 of the first embodiment has a substrate 11.

The substrate 11 is configured by a semiconductor substrate such as a known single crystal Si substrate, a silicon-on-insulator (SOI) substrate, or a silicon-on-sapphire (SOS) substrate, whose uppermost layer is a Si layer in any case. In FIG. 3, a single crystal Si substrate is employed as the substrate 11.

In the first embodiment, the substrate 11 preferably has a high resistance for the sake of improving high-frequency property of the semiconductor device 10. More specifically, a so-called semi-insulating substrate having a resistance of at least 1000Ω or higher is preferably employed as the substrate 11.

In the semiconductor device 10 of the embodiment, a buffer layer 13 is formed on the Si layer of the substrate 11. In the first embodiment shown in FIG. 3, the single crystal Si substrate having the Si layer is used as the substrate 11, and the buffer layer 13 is formed on a substrate surface 11a of the substrate 11.

The buffer layer 13 has a so-called multi-layered structure for the sake of decreasing stress occurring when the semiconductor device 10 is driven.

That is, the buffer layer 13 is constructed by alternately stacking a plurality of the first layers 15 and a plurality of the second layers 17. FIG. 3 illustrates one example of the buffer layer 13 having a layer-stacked structure in which three first-layers 15 and four second-layers 17 are alternately stacked.

Material of the first layers 15 and the second layers 17 are selected depending on materials of the third layer 19 and the fourth layer 21 respectively serving as an electron transit layer and an electron supplying layer described later. That is, it is necessary that the first layer 15 and the second layer 17 are composed of materials having similar to or the same lattice constants as the third layer 19 and the fourth layer 21. It is intended that crystal lattice constants of the first and second layers of the buffer layer 13 are favorably matched with crystal lattice constants of the third layer 19 and the fourth layer 21 formed on the buffer layer 13 and ease of manufacturing processes is enhanced. In the first embodiment, the first layer 15 is thus composed of the same material as that of the third layer 19, and the second layer 17 is composed of a material having a lattice constant similar to those of the first layer 15 and the third layer 19.

More specifically, if the third layer 19 serving as the electron transit layer is composed of GaN and if the fourth layer 21 serving as the electron supplying layer is composed of AlGaN, then the first layer 15 of the buffer layer 13 is preferably composed of GaN and the second layer 17 of the buffer layer 13 is preferably composed of either AlN or AlGaN.

In addition, if the third layer 19 serving as the electron transit layer is composed of GaAs and if the fourth layer 21 serving as the electron supplying layer is composed of AlGaAs, then the first layer 15 of the buffer layer 13 is preferably composed of GaAs and the second layer 17 of the buffer layer 13 is preferably composed of either AlAs or AlGaAs.

Here, if the first layer 15 and the second layer 17 are composed by the combination of the materials described above, a bandgap of the material composing the first layer 15 is narrower than that of the material composing the second layer 17. An energy band gap discontinuity equal to a difference in electron affinities of the two layers 15 and 17 occurs at a heterojunction between the first layer 15 and the second layer 17 in a thermal equilibrium condition. The first layer 15 and the second layer 17 thus have energy band structures so that a 2DEG layer is formed in a region of the first layer 15 where the energy level of conduction band of the first layer 15 is below the Fermi level. That is, carriers are generated in the region of the first layer 15 near the interface between the first layer 15 and the second layer 17, thus possibly forming the 2DEG layer.

As described above, the generation of the 2DEG layer in the first layer 15, that is, in the buffer layer 13 may degrade high frequency property of the semiconductor device 10.

In the first embodiment, a p-type impurity is introduced into the first layers 15 in order to suppress the generation of the 2DEG layer that may be formed in the first layer 15 of the layer-stacked structure having the first layer 15 and the second layer 17 or in order to deactivate the 2DEG layer.

Thus, the density of carriers generated in the layer-stacked structure having the first layer 15 and the second layer 17 is decreased by the introduction of the p-type impurity into the first layers 15. This results in the suppression of the generation of the 2DEG layer in the first layer 15.

According to the embodiment of the present invention, for example, Zn is preferably employed as the p-type impurity to decrease the carrier density. In order to deactivate the 2DEG layer in the first layer 15, the first layer 15 preferably has a carrier density of 1×10¹⁵ cm⁻³ or lower. Therefore, in the first embodiment, Zn is introduced in the first layer so that the first layer 15 preferably has a Zn impurity concentration of, for example, at least 1×10¹⁸ cm⁻³ or higher and more preferably about 5×10¹⁸ cm⁻³.

To reduce the stress described above, one first layer 15 with a thickness of 16 nm and one second layer 17 with a thickness of 4 nm are alternately stacked so that the buffer layer 13 is obtained preferably having about 20 to 40 layers of the first layer 15 layer and about 20 to 40 layers of the second layer 17 layer.

In the layer-stacked structure of the first layers 15 and the second layers 17 forming the buffer layer 13, both the lowermost layer 13a and the uppermost layer 13b are preferably the second layer 17. Thus, by arranging the second layer 17 in the lowermost and uppermost layers 13a and 13b of the buffer layer 13, the p-type impurity introduced in the first layer 15 can be prevented from diffusing into other layers.

According to the embodiment, an additional buffer layer (not shown) different from the buffer layer 13 may be formed between the substrate 11 and the buffer layer 13, which is intended to highly match crystal lattices of the first and second layers of the buffer layer 13 to that of the substrate 11.

In this case, the additional buffer layer formed between the substrate 11 and the buffer layer 13 is preferably composed of a material whose lattice constant is similar to or the same as those of the first layer 15 and the second layer 17. More specifically, if the first layer 15 is composed of, for example, GaN and if the second layer 17 is composed of, for example, AlN, then the additional buffer layer formed between the substrate 11 and the buffer layer 13 is preferably formed by sequentially stacking, for example, an AlN layer and a AlGaN layer.

In the semiconductor device 10 of the embodiment, the third layer 19 serving as the electron transit layer is formed on the buffer layer 13 and the fourth layer 21 serving as the electron supplying layer is formed on the third layer 19.

As described above, both the third layer 19 and the fourth layer 21 are composed of materials whose lattice constants are similar to or the same as those of the materials composing the first layer 15 and the second layer 17.

Therefore, if the first layer 15 is composed of GaN and the second layer 17 is composed of either AlN or AlGaN, then the electron transit layer, that is, the third layer 19 is preferably composed of GaN, more specifically, an un-intentionally-doped (UID) GaN. In addition, the electron supplying layer, that is, the fourth layer 21 is preferably composed of AlGaN, more specifically, UID-AlGaN.

Moreover, if the first layer 15 is composed of GaAs and the second layer 17 is composed of either AlAs or AlGaAs, then the electron transit layer, that is, the third layer 19 is preferably composed of GaAs, more specifically, UID-GaAs. In addition, the electron supplying layer, that is, the fourth layer 21 is preferably composed of AlGaAs, more specifically, UID-AlGaAs.

By stacking the third layer 19 and the fourth layer 21 composed of the combination of materials described above, a heterojunction is formed at an interface 19a between the third layer 19 and the fourth layer 21. Ascribing to a difference of energy band gaps between the third layer 19 and the fourth layer 21, the 2DEG 23 is formed in a region near the interface 19a between the third layer 19 and the fourth layer 21.

Moreover, in the semiconductor device 10 of the embodiment, if the third layer 19 has a layer-stacked structure in which GaN layers are stacked and if the fourth layer 21 has a layer-stacked structure in which AlGaN layers are stacked, then a thin AlN layer may be formed between the third layer 19 and the fourth layer 21 for the sake of increasing the carrier density of the 2DEG layer 23 and improving electron mobility. In addition, if the third layer 19 has a layer-stacked structure in which GaAs layers are stacked and if the fourth layer 21 has a layer-stacked structure in which the AlGaAs layers are stacked, then a thin AlAs layer (not shown) may be formed between the third layer 19 and the fourth layer 21.

In the semiconductor device 10 of the embodiment, for example, a cap layer (not shown) may be formed on the fourth layer 21 for the sake of preventing a surface 21a of the electron supplying layer, that is, of the fourth layer 21 from being contaminated. If the third layer 19 has a layer-stacked structure in which GaN layers are stacked and if the fourth layer 21 has a layer-stacked structure in which AlGaN layers are stacked, then the cap layer is preferably composed of GaN. In addition, if the third layer 19 has a layer-stacked structure in which GaAs layers are stacked and if the fourth layer 21 has a layer-stacked structure in which AlGaAs layers are stacked, then the cap layer is preferably composed of GaAs.

The semiconductor 10 of the embodiment has an element separating region 27 by which one of element region 25 formed on the substrate 11 is separated from another.

The element separating region 27 is formed on the substrate 11 to electrically insulate one of the element regions 25 from another and, for example, Ar ion is implanted from the surface 21a of the fourth layer 21 toward a lower portion of the 2DEG layer 23.

A gate electrode 29, a first main electrode 31a, and a second main electrode 31b are formed on the element region 25.

The gate electrode 29 is formed on the fourth layer 21 of, for example, Ni and Au.

The first and second main electrodes 31a and 31b are formed on the fourth layer 21 of, for example, Ti and Al. The first and second main electrodes 31a and 31b are separated from each other to sandwich the gate electrode 29 therebetween and to face each other. The first and second main electrodes 31a and 31b, which provide ohmic contacts to the electron supplying layer of the fourth layer 21, serve as ohmic electrodes, one of which serves as a source electrode and the other of which serves as a drain electrode.

Thus, in the semiconductor device 10 of the embodiment having the components described above, the HEMT is constructed in which the 2DEG layer 23 serves as a current path flowing an electric current between the first and second main electrodes 31a and 31b.

In the semiconductor device 10 of the embodiment described above, the p-type impurity is introduced into the first layers 15 of the buffer layer 13. Therefore, it is possible to decrease the carrier density of the first layers 15 of the layer-stacked structure in which the first layers 15 and the second layers 17 are alternately stacked. As a result, the generation of the 2DEG layers in the first layers 15 can be suppressed, in other words, the 2DEG layers in the first layers 15 can be deactivated.

Experiments were carried out by the inventor of the present invention to examine that the 2DEG layer could be deactivated by introducing the p-type impurity.

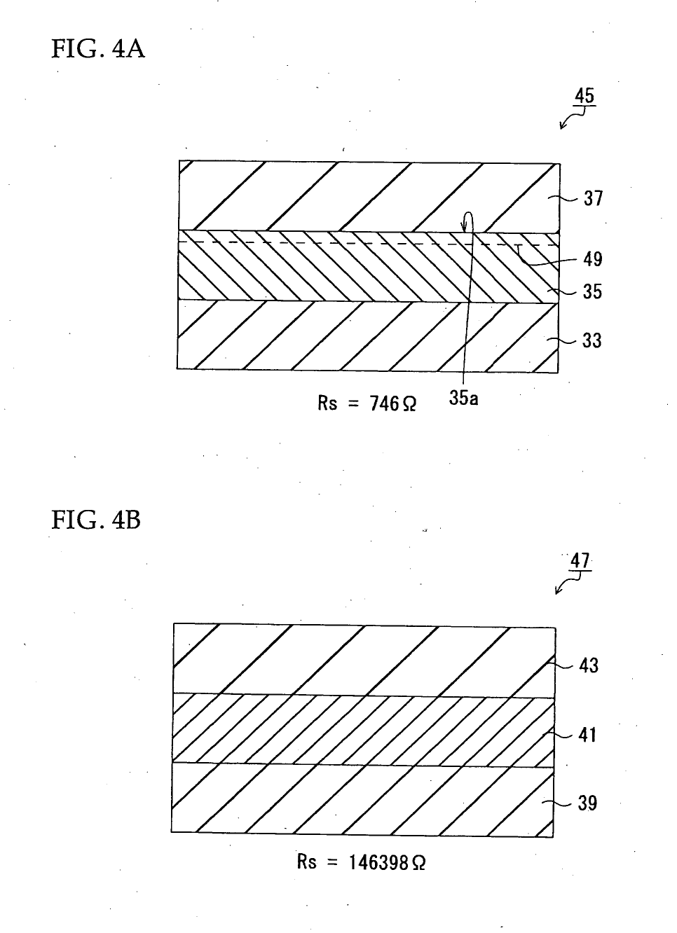

FIGS. 4A and 4B are diagrams illustrating experiment setups to confirm effect of introduction of the p-type impurity. Each of FIGS. 4A and 4B is a cross-sectional view of a section of a structural body of a sample for the experiment taken in a thickness direction.

In the experiments, two samples were examined as shown in FIGS. 4A and 4B.

In the structural body 45 shown in FIG. 4A, a UID-GaN layer 35 with a thickness of 1000 nm and a UID-AlGaN layer 37 with a thickness of 20 nm are stacked sequentially on a single crystal substrate 33. In the structural body 45, due to a difference of energy band gaps at a heterointerface 35a between the GaN and AlGa layers, carriers are generated in the UID-GaN layer 35, thus providing a 2DEG layer 49.

Also, in the structural body 47 shown in FIG. 4B, a GaN layer 41 with a thickness of 1000 nm and a UID-AlGaN layer 43 with a thickness of 20 nm are sequentially stacked on a single crystal silicon substrate 39. A p-type impurity of Zn is introduced into the GaN layer 41 so that the Zn impurity concentration is 5×10¹⁸ cm⁻³.

Sheet resistances of the structural bodies 45 and 47 shown in FIGS. 4A and 4B are measured by the inventor.

As, a result, the structural body 45 shown in FIG. 4A has a sheet resistance of 746Ω, including the UID-GaN layer 35 in which the 2DEG layer 49 is generated. In contrast, the structural body 47 shown in FIG. 4B has a sheet resistance of 146398Ω.

A relationship between the sheet resistance “RS” and the carrier density “n” is expressed by the following equation (1):

RS=(1/nqμ)(I/S) (1)

where “q” denotes electron charge, “μ” denotes electron mobility, “I” denotes a length of a structural body, and “S” denotes a cross sectional area of the structural body along a thickness direction.

As is apparent from the equation (1), an increase in the sheet resistance “RS” will decrease the carrier density “n”. The above results show that the resistance is greatly increased in the structural body 47 into which the p-type impurity is introduced when compared with the structural body 45 into which no p-type impurity is introduced. Therefore, it can be confirmed from the result that the introduction of the p-type impurity is effective in decreasing the carrier density, that is, in deactivating the 2DEG layer.

Next, a method for manufacturing a semiconductor device 10 of the embodiment will be described. The manufacturing method includes first and second processes. Hereinafter, these processes will now be described, in order, from the first process.

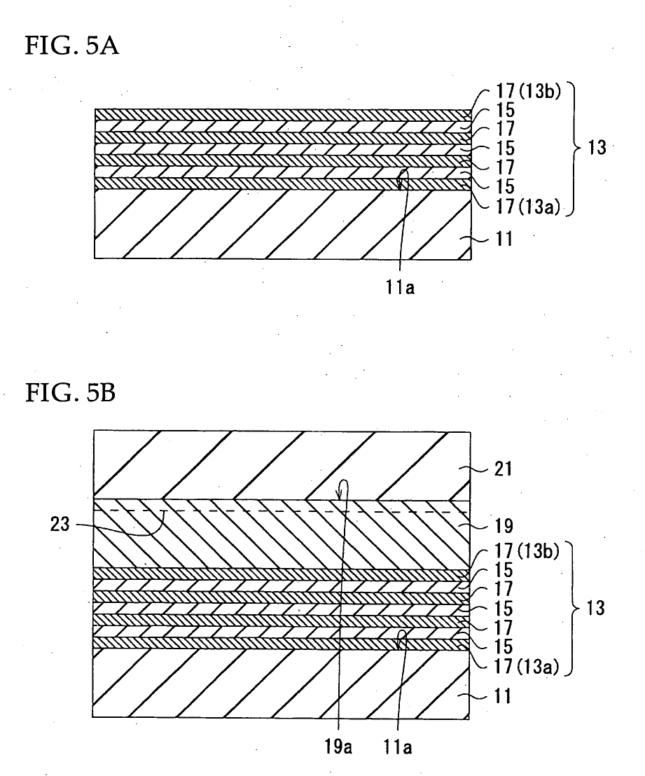

FIGS. 5A and 53 are process diagrams illustrating the method for manufacturing the semiconductor device 10 of the embodiment. Each of FIGS. 5A and 5B shows a cross-sectional view of a structural body obtained in each manufacturing process taken in a thickness direction of the substrate.

In the first process, a buffer layer 13 is formed on a substrate 11 whose uppermost layer is a Si layer so as to obtain a structural body as shown in FIG. 5.

The substrate 11 is formed of a semiconductor substrate such as a known single crystal Si substrate, a SOI substrate, or a SOS substrate, whose uppermost layer is a Si layer. In FIG. 5A, an example using the single crystal Si substrate as the substrate 11 is shown.

In the embodiment, the substrate 11 having high resistance is preferably employed for the sake of improving frequency property of the semiconductor device 10. More specifically, a so-called semi-insulating substrate having its resistance of at least 1000Ω or higher is preferably employed as the substrate 11.

The buffer layer 13 is formed by alternately stacking a first layer 15 and a second layer to reduce the stress described above, so that a plurality of first layers 15 and a plurality of second layers 17 are alternately formed on the Si layer of the substrate 11. In the example of FIG. 5, since the single crystal Si substrate including the Si layer is employed as the substrate 11, the buffer layer 13 is formed on a substrate surface 11a of the substrate 11. FIG. 5A shows the example in which three of first layer 15 and four of second-layer 17 are alternately stacked on the substrate 11 to form the buffer layer 13.

As described above, materials of the first layer 15 and the second layer 17 are selected depending on materials of a third layer 19 and a fourth layer 21 which are formed in the subsequent second process.

That is, as explained already, it is necessary that both the first layers 15 and the second layers 17 are composed of materials having lattice constants similar to or the same as those of the third layer 19 and the fourth layer 21 to be formed on the buffer layer 13.

That is, it is necessary that the first layer 15 and the second layer 17 are composed of materials having similar or same lattice constants of the third layer 19 and the fourth layer 21. It is intended that crystal lattice constants of the first and second layers of the buffer layer 13 are favorably matched to crystal lattice constants of the third layer 19 and the fourth layer 21 formed on the buffer layer 13 and that the manufacturing processes can be performed more easily. Thus, in the first process, the first layers 15 are composed of the same material as the third layer 19 described later and the second layers 17 are composed of a material having a lattice constant similar to or the same as those of the first layer 15 and third layer 19.

More specifically, if the third layer is composed of GaN and if the fourth layer is composed of AlGaN, then the first layer 15 is preferably composed of GaN and the second layer 17 is preferably composed of either AlN or AlGaN.

Moreover, the buffer layer 13 is formed in the first process by introducing the p-type impurity into the first layers 15. This is intended to decrease the carrier density by using a combination of the materials for the first and second layers 15, 17 and to deactivate the 2DEG layer generated in the first layer 15 by decreasing the carrier density as described.

According to the embodiment, it is preferable that the p-type impurity to decrease the carrier density is, for example, Zn.

In order to deactivate the 2DEG in the first layer 15, the carrier density is preferably 1×10¹⁵ cm⁻³ or lower. Therefore, in the first process, Zn is introduced into the first layer 15 so that Zn impurity concentration is preferably 1×10¹⁸ cm⁻³ or higher and more preferably about 5×10¹⁸ cm⁻³.

More specifically, in the first process, the first layers 15 and the second layers 17 composed of the described materials are alternately formed by using for example, a known metal organic chemical vapor deposition (MOCVD) method or a molecular beam epitaxy (MBE) method. When the first layer 15 is formed, the p-type impurity of, for example, Zn in the form of gaseous dimethylzinc (DMZn) is preferably added into the material described above. As a result, the first layers 15, in which the p-type impurity is introduced, are formed.

Thus, by forming the first layers 15 into which the p-type impurity is introduced, the density of the carrier generated is decreased in the layer-stacked structure in which the first layer 15 and the second layer 17 are stacked. As a result, the generation of the 2DEG layers in the first layers 15 can be suppressed or deactivated.

In the first process, one first layer 15 with a thickness of 16 nm and one second layer 17 with a thickness of 4 nm are alternately stacked so as to form a buffer layer 13 having a layer-stacked structure including 20-40 first layers 15 and 20-40 second layers 17 for the sake of reducing the stress described above.

Moreover, in the first process, the buffer layer 13 having the layer-stacked structure of the alternatively stacked first and second layers 15 and 17 is preferably configured to include a lowermost layer 13a and an uppermost layer 13b, both of which are the second layers 17. The lowermost and uppermost layers 13a and 13b of the buffer layer 13 are formed of the second layer 17, and thus the p-type impurity introduced into the first layers 15 can be prevented from diffusing to other layers.

Here, as described above, in the first embodiment, an additional buffer layer (not shown) different from the buffer layer 13 may be formed between the substrate 11 and the buffer layer 13 so that crystal lattices of the first and second layers of the buffer layer 13 are highly matched to that of the substrate 11. In this case, prior to the formation of the buffer layer 13, the additional buffer layer composed of a material having a lattice constant similar to or the same as those of the first layer 15 and the second layer 17 is preliminarily formed on the substrate 11 for the sake of achieving the lattice matching.

More specifically, if the first layer 15 is composed of, for example, GaN and if the second layer 17 is composed of, for example, AlN, then, for example, AlN layers and AlGaN layers are sequentially stacked on the substrate 11 so as to form the buffer layer with a lattice matching. The buffer layer 13 described above is formed on the additional buffer layer with the lattice matching.

Next, in the second process, a third layer 19 serving as the electron transit layer and a fourth layer 21 serving as the electron supplying layer are formed on the buffer layer 13, so that a structural body of FIG. 5B is obtained.

As described above, in the embodiment, the third layer 19 and the fourth layer 21 are composed of materials having lattice constants similar to or the same as those of materials of the first layer 15 and the second layer 17.

If the first layer 15 is composed of GaN and the second layer 17 is composed of either AlN or AlGaN in the first process as described above, then the third layer 19 is preferably composed of GaN, in more detail, UID-GaN and the fourth layer 21 is composed of AlGaN, in more detail, UID-AlGaN in the second process.

Moreover, if the first layer 15 is composed of GaAs and the second layer 17 is composed of either AlAs or AlGaAs in the first process as described above, then the third layer 19 is preferably composed of GaAs, in more detail, UID-GaAs and the fourth layer 21 is preferably composed of AlGaAs, in more detail, UID-AlGaAs in the second process.

In the second process, the materials described above are preferably deposited by, for example, a known MOCVD method so as to form the third and fourth layers 19 and 21.

By stacking the third layer 19 and the fourth layer 21 composed of such materials described above, a heterojunction is formed at an interface 19a between the third layer 19 and the fourth layer 21. As a result, ascribing to an energy band gap difference between the third layer 19 and the fourth layer 21, the 2DEG 23 is formed near at the interface 19a between the third layer 19 and the fourth layer 21.

Moreover, as described above, in the semiconductor device of the embodiment, if the third layer 19 having a layer-stacked structure of GaN layers is formed and if the fourth layer 21 having a layer-stacked structure of AlGaN layers is formed, then a thin AlN layer may be formed between the third layer 19 and the fourth layer 21 for the sake of increasing carrier density of the 2DEG layer 23 and improving electron mobility of the 2DEG layer 23. In addition, if the third layer 19 has a layer-stacked structure in which GaAs layers are stacked and the fourth layer 21 has a layer-stacked structure in which AlGaAs layers are stacked, then a thin AlAs layer (not shown) may be formed between the third layer 19 and the fourth layer 21

In this case, after forming the third layer 19 and prior to forming the fourth layer 21, the thin AlN layer or thin AlAs layer are formed by using, for example, a known MOCVD method. After that, the fourth layer 21 is formed on the thin AlN layer or thin AlAs layer.

As described above, in the semiconductor device of the embodiment, with the aim of preventing a surface 21a of the fourth layer 21 serving as the electron supplying layer from being contaminated, for example, a cap layer (not shown) may be formed on the fourth layer 21. In this case, after forming the fourth layer 21, the cap layer is preferably formed by, for example, a known MOCVD method. Moreover, as explained already, for example, if the third layer 19 having a layer-stacked structure of GaN layers is formed and if the fourth layer 21 having a layer-stacked structure of AlGaN layers is formed, then the cap layer is preferably composed of GaN. In addition, if the third layer 19 having a layer-stacked structure of GaAs layers is formed and if the fourth layer 21 having a layer-stacked structure of AlGaAs layers is formed, then the cap layer is preferably composed of GaAs.

Next, after the second process, element separating regions 27, a gate electrode 29, a first main electrode 31a, and a second main electrode 31b are formed to obtain the structural body of FIG. 3.

As described above, the element separating region 27 is formed to electrically separate one of the element region 25 formed on the substrate 11 from another. Therefore, the element separating region 27 is formed by implanting Ar ion from a surface 21a of the fourth layer 21 toward a lower portion of the 2DEG layer 23.

Then, after forming the element separating regions 27, the gate electrode 29, the first main electrode 31a and the second main electrode 31b are formed in the element region 25.

More specifically, the gate electrode 29 is preferably formed on the fourth layer 21. The fourth layer 21 is composed of, for example, Ni and Au by, for example, a known electron beam (EB) evaporation method.

Also, the first main electrode 31a and the second main electrode 31b are preferably formed of, for example, Ti and Al by, for example, a known EB evaporation method. The first and second main electrodes 31a and 31b separated from each other sandwich the gate electrode 29 therebetween and face each other. As explained above, the first and second main electrodes 31a and 31b, which provide ohmic contacts to the electron supplying layer of the fourth layer 21, serve as ohmic electrodes, one of which serves as a source electrode and the other of which serves as a drain electrode.

Thus, in the semiconductor device manufactured by the method of the embodiment, by forming each component as described above, the HEMT is constructed in which the 2DEG layer 23 serves as a current path to flow an electric current between the first and second main electrodes 31a and 31b.

According to the manufacturing method of the semiconductor device of the embodiment described above, the p-type impurity is introduced into the first layers 15 of the buffer layer 13. As a result, in the layer-stacked structure in which the first and second layers 15 and 17 are alternately stacked, it is possible to decrease the carrier density of the first layer 15. Further, in the semiconductor device manufactured by the manufacturing method of the embodiment, the generation of the 2DEG layers in the first layers can be suppressed, that is, the deactivation of the 2DEG layers can be achieved.

Moreover, in the embodiment of the present invention, the semiconductor device and the method of manufacturing the same of the embodiment has been described. In the description of the manufacturing method, the configuration of GaN/AlGaN-HEMT in which the third layer 19 and the fourth layer 21 are composed of GaN and AlGaN, respectively, and the configuration of the GaAs/AlGaAs-HEMT in which the third layer 19 and the fourth layer 21 are composed of GaAs and AlGaAs, respectively, are included. However, the embodiment is not limited to the examples described above and the embodiment can be modified to various compound semiconductor devices such as an InP-based HEMT so long as the compound semiconductor device includes a substrate whose uppermost layer is a Si layer and a buffer layer having a multi-layer film structure.

This application is based on Japanese Patent Application No. 2009-097085 which is herein incorporated by reference.

What is claimed is:

1. A semiconductor device comprising:
a substrate whose uppermost layer is a Si layer;
a buffer layer formed by alternately stacking a plurality of first layers and a plurality of second layers on said Si layer;
a third layer for serving as an electron transit layer formed on said buffer layer; and
a fourth layer for serving as an electron supplying layer formed on said third layer;
wherein said first layers are composed of a material identical to a material of said third layers and wherein a p-type impurity is introduced into said first layers so as to deactivate 2-dimensional electron gas layers formed in said first layers near interfaces between said first and second layers.

2. The semiconductor device according to claim 1, wherein said first layers are composed of GaN, said second layers are composed of any one of AlN and AlGaN, said third layers are composed of GaN, and said fourth layers are composed of AlGaN.

3. The semiconductor device according to claim 1, wherein said first layers are composed of GaAs, said second layers are composed of any one of AlAs and AlGaAs, and said third layers are composed of GaAs and said fourth layers are composed of AlGaAs.

4. The semiconductor device according to claims 1, wherein said p-type impurity is Zn.

5. The semiconductor device according to claim 4, wherein said p-type impurity having a concentration of 5×10¹⁸ cm⁻³ is introduced into said first layers.

6. The semiconductor device according to claim 1, wherein both of lowermost and uppermost layers of said buffer layer are said second layer.

7. A method for manufacturing a semiconductor device comprising:
a first step of alternately stacking a plurality of first layers and a plurality of second layers on a substrate whose uppermost layer is a Si layer so as to form a buffer layer on said Si layer; and
a second step of forming sequentially a third layer serving as an electron transit layer and a fourth layer serving as an electron supplying layer on said buffer layer;
wherein, in said first step, said first layers are composed of a material identical to a material said third layer and wherein a p-type impurity is introduced into said first layers so as to deactivate 2-dimensional electron gas layers formed in said first layers near interfaces between said first layers and said second layers.

8. The method for manufacturing the semiconductor device according to claim 7, wherein said first layer is composed of GaN, said second layer is composed of any one of AlN and AlGaN, said third layer is composed of GaN, and said fourth layer is composed of AlGaN.

9. The method for manufacturing the semiconductor device according to claim 7, wherein said first layers are composed of GaAs, said second layers are composed of any one of AlAs and AlGaAs, said third layers are composed of GaAs, and said fourth layers are composed of AlGaAs.

10. The method for manufacturing the semiconductor device according to claim 7, wherein said p-type impurity is Zn.

11. The method for manufacturing the semiconductor device according to claim 10, wherein said p-type impurity having a concentration of 5×10¹⁸ cm⁻³ is introduced into said first layer.

12. The method for manufacturing a semiconductor device according to claim 7, wherein both of lowermost and uppermost layers of said buffer layer are said second layer.

13. The semiconductor device according to claim 1, wherein said material of said first layer has an energy band gap narrower than that of a material of said second layer.

14. The method for manufacturing a semiconductor device according to claim 7, wherein said material of said first layer has an energy band gap narrower than that of a material of said second layer.

15. The semiconductor device according to claim 1 further comprising an additional buffer layer formed between said Si layer and said buffer layer.

16. The method for manufacturing a semiconductor device according to claim 7 further comprising a step of forming an additional buffer layer formed between said Si layer and said buffer layer.

17. The semiconductor device according to claim 1 further comprising a thin layer formed between said third and fourth layers, for increasing a carrier density of 2-dimensional electron gas layer generated in said third layer near an interface between said third and fourth layers.

18. The method for manufacturing a semiconductor device according to claim 7, further comprising a step of forming a thin layer formed between said third and fourth layers, for increasing a carrier density of 2-dimensional electron gas layer generated in said third layer near an interface between said third and fourth layers.
